(19) United States
(12) Patent Application Publication
(10) Pub. No.: US 2023/0253527 A1
(43) Pub. Date: Aug. 10, 2023

(54) SEMICONDUCTOR LIGHT-EMITTING DEVICE AND METHOD OF MANUFACTURING THE SAME

(71) Applicant: SAMSUNG ELECTRONICS CO., LTD., Suwon-si (KR)

(72) Inventors: Yongseok CHOI, Suwon-si (KR); Suyeol LEE, Seongnam-si (KR); Jeongwook LEE, Seongnam-si (KR); Youngjin CHOI, Seoul (KR)

(21) Appl. No.: 18/103,629

(22) Filed: Jan. 31, 2023

(30) Foreign Application Priority Data
Feb. 4, 2022 (KR) 10-2022-0015072

(51) Int. Cl. H01L 33/38; H01L 33/32; H01L 33/06; H01L 33/24

(52) U.S. Cl. CPC H01L 33/382; H01L 33/32; H01L 33/06; H01L 33/24

(57) ABSTRACT

A semiconductor light-emitting device includes a first conductivity-type semiconductor layer having, in an upper portion thereof, a plurality of rods spaced apart from each other, a plurality of active layers respectively formed on upper surfaces of the plurality of rods, a plurality of second conductivity-type semiconductor layers respectively formed on upper surfaces of the plurality of active layers, an insulating spacer conformally formed between the plurality of rods, surrounding all sidewalls of each of the plurality of active layers, and covering portions of sidewalls of each of the plurality of second conductivity-type semiconductor layers, a first electrode layer in contact with a lower portion of the first conductivity-type semiconductor layer, and a second electrode layer filling an inner space of the insulating spacer and in contact with the plurality of second conductivity-type semiconductor layers.

### CROSS-REFERENCE TO RELATED APPLICATION

This application is based on and claims priority under 35 U.S.C. § 119 to Korean Patent Application No. 10-2022-0015072, filed on Feb. 4, 2022, in the Korean Intellectual Property Office, the disclosure of which is incorporated by reference herein in its entirety.

### BACKGROUND

### 1. Field

Embodiments relate to a semiconductor light-emitting device and a method of manufacturing the semiconductor light-emitting device, and more particularly, to a semiconductor light-emitting device having excellent light emitting characteristics and a method of manufacturing the semiconductor light-emitting device.

### 2. Description of the Related Art

Light-emitting devices are known as next-generation light sources that have advantages, such as long lifespan, low power consumption, fast response speed, and environmental friendliness, compared to existing light sources, and are attracting attention as important light sources in various products, e.g., lighting apparatuses and backlights of display apparatuses. For example, a semiconductor light-emitting device may be implemented in a display apparatus.

In general, a display apparatus may include a display panel and a backlight unit. Recently, a display apparatus using a semiconductor light-emitting device as one pixel has been proposed. Accordingly, there is a demand for a semiconductor light-emitting device to have a simple structure with low product defects while having enhanced light emitting characteristics.

### SUMMARY

According to an aspect of embodiments, there is provided a semiconductor light-emitting device including: a first conductivity-type semiconductor layer including, in an upper portion thereof, a plurality of rods apart from each other; a plurality of active layers respectively formed on upper surfaces of the plurality of rods; a plurality of second conductivity-type semiconductor layers respectively formed on upper surfaces of the plurality of active layers; an insulating spacer conformally formed between the plurality of rods, surrounding all sidewalls of each of the plurality of active layers, and covering portions of sidewalls of each of the plurality of second conductivity-type semiconductor layers; a first electrode layer in contact with a lower portion of the first conductivity-type semiconductor layer; and a second electrode layer filling an inner space of the insulating spacer and in contact with the plurality of second conductivity-type semiconductor layers.

According to another aspect of embodiments, there is provided a semiconductor light-emitting device including: a first conductivity-type semiconductor layer including mesa structures apart from each other; an active layer formed on an upper surface of each of the mesa structures; an insulating spacer conformally formed between the mesa structures, surrounding all sidewalls of the active layer, covering lower ends of sidewalls of the second conductivity-type semiconductor layer, and having an round upper outer wall; a first electrode layer in contact with the first conductivity-type semiconductor layer; and a second electrode layer filling an inner space of the insulating spacer and in contact with an upper surface of the second conductivity-type semiconductor layer and upper ends of the sidewalls of the second conductivity-type semiconductor layer.

According to yet another aspect of embodiments, there is provided a semiconductor light-emitting device including: a sapphire substrate; an undoped gallium nitride layer formed on the sapphire substrate; an n-type gallium nitride layer including, in an upper portion thereof, a plurality of rods apart from each other; a plurality of active layers respectively formed on upper surfaces of the plurality of rods; a plurality of p-type gallium nitride layers respectively formed on upper surfaces of the plurality of active layers; an insulating spacer conformally formed between the plurality of rods, surrounding all sidewalls of each of the plurality of active layers, and covering portions of sidewalls of each of the plurality of p-type gallium nitride layers; an n-electrode layer in contact with a lower portion of the n-type gallium nitride layer; and a p-electrode layer filling an inner space of the insulating spacer and in contact with the plurality of p-type gallium nitride layers.

According to still another aspect of embodiments, there is provided a method of manufacturing a semiconductor light-emitting device, the method including: forming a first conductivity-type semiconductor layer on a substrate; forming a sacrificial layer on the first conductivity-type semiconductor layer; forming a mask pattern on the sacrificial layer; patterning the sacrificial layer and the first conductivity-type semiconductor layer by using the mask pattern as an etching mask to form a plurality of rods apart from each other in an upper portion of the first conductivity-type semiconductor layer; forming an insulating spacer to conformally surround upper portions of the sacrificial layer and the first conductivity-type semiconductor layer; etching an upper surface of the insulating spacer to expose an upper surface of the sacrificial layer; removing the sacrificial layer; forming a plurality of active layers on upper surfaces of the plurality of rods; forming a plurality of second conductivity-type semiconductor layers on upper surfaces of the plurality of active layers; removing a portion of the insulating spacer to expose a lower portion of the first conductivity-type semiconductor layer and forming a first electrode; and forming a second electrode to cover all of the plurality of second conductivity-type semiconductor layers and to fill a space between insulating spacers.

### BRIEF DESCRIPTION OF THE DRAWINGS

Features will become apparent to those of skill in the art by describing in detail exemplary embodiments with reference to the attached drawings, in which:

FIG. 1 is a plan view of a semiconductor light-emitting device according to an embodiment;

FIG. 2A is a cross-sectional view taken along line A-A′ in FIG. 1;

FIG. 2B is an enlarged view of region CC in FIG. 2A;

FIG. 2C is another enlarged view of region CC in FIG. 2A;

FIGS. 3 to 6 are views of semiconductor light-emitting devices according to other embodiments;

FIG. 7 is a flowchart of a method of manufacturing a semiconductor light-emitting device, according to an embodiment;

FIGS. 8 to 16 are cross-sectional views of stages in a method of manufacturing a semiconductor light-emitting device, according to an embodiment;

FIG. 17 is a schematic cross-sectional view of a white light source module employable in a lighting apparatus as a semiconductor light-emitting device according to an embodiment;

FIG. 18 is a CIE chromaticity diagram illustrating a perfect radiator spectrum that is usable for a semiconductor light-emitting device according to an embodiment;

FIG. 19 is a schematic view of a cross-sectional structure of a quantum dot (QD), which may be used as a wavelength conversion material for a semiconductor light-emitting device according to an embodiment;

FIG. 20 is a perspective view of a vehicle including a semiconductor light-emitting device according to an embodiment;

FIG. 21 is a perspective view of a flat-panel lighting apparatus including a semiconductor light-emitting device according to an embodiment; and

FIG. 22 is an exploded perspective view of a lighting apparatus including a semiconductor light-emitting device according to an embodiment.

### DETAILED DESCRIPTION

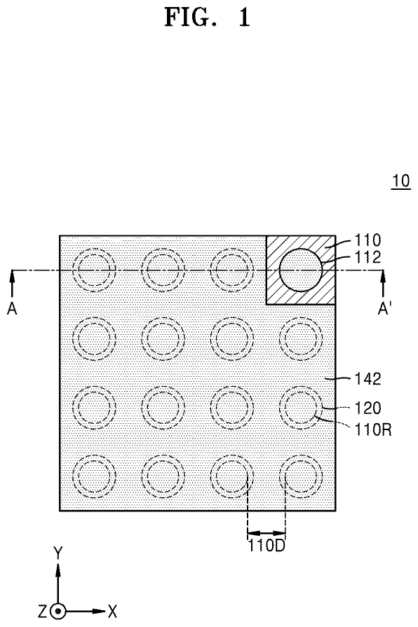

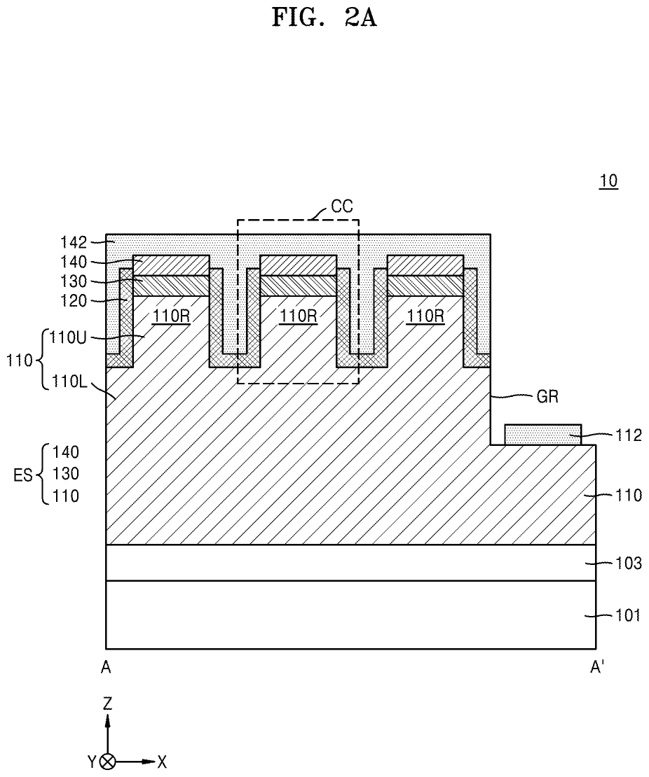

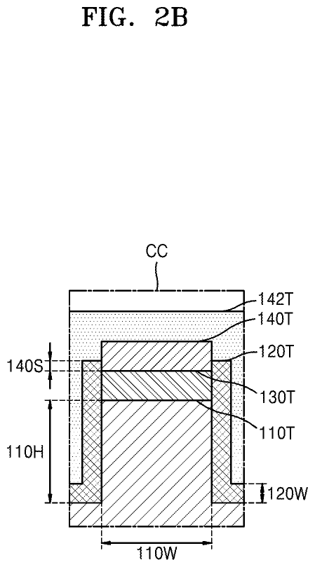

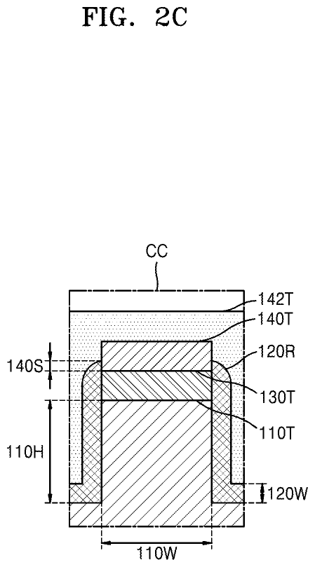

FIG. 1 is a plan view of a semiconductor light-emitting device 10 according to an embodiment, FIG. 2A is a cross-sectional view taken along line A-A′ in FIG. 1, FIG. 2B is an enlarged view of region CC of FIG. 2A, and FIG. 2C is another enlarged view of the CC of FIG. 2A. In addition, for convenience of description, in FIG. 1, it is assumed that a second electrode layer 142 is transparent, and shapes of a plurality of rods 110R and an insulating spacer 120, disposed under the second electrode layer 142, are indicated by a dashed line.

Referring to FIGS. 1 and 2A to 2C, the semiconductor light-emitting device 10 may be formed on a substrate 101, and may include a first conductivity-type semiconductor layer 110, the insulating spacer 120, an active layer 130, and a second conductivity-type semiconductor layer 140. A stacked structure of the first conductivity-type semiconductor layer 110, the active layer 130, and the second conductivity-type semiconductor layer 140 may define, e.g., form, a light-emitting structure ES, as will be described in more detail below.

The substrate 101 may be disposed under a light-emitting structure ES to support the light-emitting structure ES. For example, as illustrated in FIG. 2A, a base layer 103 may be formed between the substrate 101 and the light-emitting structure ES. The substrate 101 may receive heat generated by the light-emitting structure ES through the base layer 103, and may externally radiate the received heat. In addition, the substrate 101 may have light-transmitting properties. The substrate 101 may include a light-transmitting material, or a material capable of having light-transmitting properties when formed to a certain thickness or less.

The substrate 101 may be an insulating, conductive, or semiconductor substrate, if necessary. For example, the substrate 101 may include at least one of sapphire (Al₂O₃), gallium nitride (GaN), silicon (Si), germanium (Ge), gallium arsenide (GaAs), zinc oxide (ZnO), silicon germanium (SiGe), silicon carbide (SiC), gallium oxide (Ga₂O₃), lithium gallium oxide (LiGaO₂), lithium aluminum oxide (LiAlO₂), magnesium aluminum oxide (MgAl₂O₄), or the like.

In some embodiments, a sapphire substrate, a silicon carbide substrate, or a silicon substrate are mainly used as the substrate 101. A sapphire substrate, which is relatively inexpensive compared to a silicon carbide substrate, is more widely used.

The substrate 101 may be completely or partially removed during a process of manufacturing the light-emitting device in order to improve optical properties or electrical properties before or after the formation of the light-emitting structure ES. For example, when a sapphire substrate is used as the substrate 101, the substrate 101 may be removed by irradiating a laser to an interface with the base layer 103 through the substrate 101. In another example, when a silicon substrate or a silicon carbide substrate is used as the substrate 101, the substrate 101 may be removed by polishing or etching.

The base layer 103 may be formed to provide a growth surface of the light-emitting structure ES. For example, the base layer 103 may include InₓAl_{y}Ga_{(1-x-y)} (0≤x≤1, 0≤y≤1), GaN, AlN, AlGaN, InGaN, InGaNAlN, or the like. If necessary, a material, e.g., ZrB₂, HfB₂, ZrN, HfN, or TiN, may be used for the base layer 103. Also, the base layer 103 may include an undoped gallium nitride layer. In some embodiments, the base layer 103 may be formed to have a multi-layered structure or may be used by gradually changing the composition thereof. In other embodiments, the base layer 103 may be omitted.

The first conductivity-type semiconductor layer 110 may include a nitride semiconductor having a composition of n-type InₓAl_{y}Ga_{(1-x-y)}N (0≤x<1, 0≤y<1, 0≤x+y<1). For example, the first conductivity-type semiconductor layer 110 may include n-type impurities, and the n-type impurities may be, e.g., silicon (Si). Alternatively, the first conductivity-type semiconductor layer 110 may include GaN including n-type impurities.

In some embodiments, the first conductivity-type semiconductor layer 110 may include a first conductivity-type semiconductor contact layer and a current diffusion layer. The impurity concentration of the first conductivity-type semiconductor contact layer may be in a range of about 2×10¹⁸ cm⁻³ to about 9×10¹⁹ cm⁻³. The thickness of the first conductivity-type semiconductor contact layer may be about 1 μm to about 5 μm. The current diffusion layer may have a structure in which a plurality of InₓAl_{y}Ga_{(1-x-y)}N (0≤x, y≤1, 0≤x+y≤1) layers having different compositions or different impurity contents are alternately stacked. For example, the current diffusion layer may have an n-type superlattice structure in which n-type GaN layers and/or AlₓIn_{y}Ga_{z}N layers (0≤x,y,z≤1, and x+y+z≠0), each having a thickness of about 1 nm to about 500 nm, are alternately stacked. The impurity concentration of the current diffusion layer may be about 2×10¹⁸ cm⁻³ to about 9×10¹⁹ cm⁻³.

The first conductivity-type semiconductor layer 110 may include an upper layer 110U and a lower layer 110L, with the upper layer 110U including a plurality of rods 110R, and the lower layer 110L supporting the plurality of rods 110R. The upper surface of the lower layer 110L of the first conductivity-type semiconductor layer 110 may have a flat plate shape in contact with the lower surfaces of the plurality of rods 110R. In other words, the first conductivity-type semiconductor layer 110 may be formed to have a mesa structure. For example, as illustrated in FIG. 2A, the plurality of rods 110R may be integral with the lower layer 110L, and may extend upwardly (e.g., along the Z-direction) from the lower layer 110L. For example, as illustrated in FIGS. 1 and 2A to 2C, the plurality of rods 110R may be spaced apart from each other in two directions (e.g., in the X-direction and the Y-direction in a matrix pattern), such that spaces between adjacent ones of the plurality of rods 110R may expose the upper surface of the lower layer 110L.

For example, as illustrated in FIG. 1, the plurality of rods 110R may be circular rods. Referring to FIG. 2B, when the plurality of rods 110R are circular rods, a height 110H of each of the plurality of rods 110R (e.g., as measured from the upper surface of the lower layer 110L to the upper surface of the rod 110R along the Z direction) may be about 100 nm to about 10 μm, and a diameter 110 W of an upper surface 110T of each of the plurality of rods 110R may be about 100 nm to about 10 μm. In addition, as illustrated in FIG. 1, a shortest distance 110D between two adjacent rods 110R among the plurality of rods 110R may be about 100 nm to about 2 μm.

The insulating spacer 120 may be conformally, e.g., and continuously, disposed to cover the upper surface of the lower layer 110L of the first conductivity-type semiconductor layer 110 and the side surface of each of the plurality of rods 110R. In addition, the insulating spacer 120 may be disposed to contact all sidewalls of the active layer 130 and portions of sidewalls of the second conductivity-type semiconductor layer 140, which will be described below. For example, the insulating spacer 120 may include silicon oxide, silicon oxynitride, silicon nitride, or aluminum oxide. In some embodiments, the insulating spacer 120 may be formed to have a stacked structure of a plurality of insulating layers. For example, a thickness 120 W of the insulating spacer 120 may be about 50 nm to about 1 μm. In some embodiments, the insulating spacer 120 may completely fill a space between each pair of adjacent ones of the plurality of rods 110R.

The insulating spacer 120 may be formed to completely surround the sidewall of each of the plurality of rods 110R, e.g., the insulating spacer 120 may completely surround all sidewalls of each of the plurality of rods 110R. The insulating spacer 120 may protrude from, e.g., above, the upper surface of each of the plurality of rods 110R. That is, the insulating spacer 120 may extend above the upper surface of each of the plurality of rods 110R, and therefore, may provide a certain empty space on the upper surface of each of the plurality of rods 110R. As will be described below, the active layer 130 and the second conductivity-type semiconductor layer 140 may be formed to fill the empty space on the upper surface of each of the plurality of rods 110R.

The insulating spacer 120 may be a mask layer exposing the upper surface 110T of each of the plurality of rods 110R. In other words, the insulating spacer 120 may function as a mask layer that provides a space for forming (or growing) the active layer 130 and the second conductivity-type semiconductor layer 140, which will be described below.

As illustrated in FIGS. 2B and 2C, the upper outer wall of the insulating spacer 120 may be a vertical sidewall or a round sidewall 120R, e.g., a rounded or curved sidewall. This may be a feature that depends on the degree of etching in the process of forming the insulating spacer 120. That is, because the upper outer wall of the insulating spacer 120 protrudes above the plurality of rods 110R, more etching may be performed on the upper outer wall of the insulating spacer 120. In this case, the upper outer wall of the insulating spacer 120 may have a shape of the round sidewall 120R. The feature may be equally applied to semiconductor light-emitting devices 15, 20, 30, and 40 according to other embodiments, which will be described below.

The active layer 130 may be disposed between the first conductivity-type semiconductor layer 110 and the second conductivity-type semiconductor layer 140. The active layer 130 may be configured to emit light having a certain energy by recombination of electrons and holes when the semiconductor light-emitting device 10 is driven. The active layer 130 may have a multi-quantum well (MQW) structure in which quantum well layers and quantum barrier layers are alternately stacked. For example, each of the quantum well layers and each of the quantum barrier layers may include InₓAl_{y}Ga_{(1-x-y)}N (0≤x, y≤1, 0≤x+y≤1) having different compositions. The quantum well layer may include InₓGa₁₋ₓN (0≤x≤1), and the quantum barrier layer may include GaN or InₓAl_{y}Ga_{(1-x-y)}N (0≤x, y≤1, 0≤x+y≤1). The thickness of the quantum well layer and the thickness of the quantum barrier layer may each range from about 1 nm to about 50 nm. The active layer 130 is not limited to the MQW structure and may have a single quantum well structure.

In an embodiment, the level of an upper surface 130T of each of the plurality of active layers 130 may be vertically lower than the level of an uppermost surface 120T of the insulating spacer 120. That is, the height level of the upper surface 130T of each of the plurality of active layers 130 may be lower than the height level of an uppermost surface 120T of the insulating spacer 120 along the Z-direction relative to the bottom surface of the first conductivity-type semiconductor layer 110. In addition, the area of the upper surface 130T of each of the plurality of active layers 130 may be substantially the same as the area of the upper surface 110T of each of the plurality of rods 110R.

The second conductivity-type semiconductor layer 140 may be a nitride semiconductor layer having a composition of p-type InₓAl_{y}Ga_{(1-x-y)}N (0≤x<1, 0≤y<1, 0≤x+y<1). For example, the second conductivity-type semiconductor layer 140 may include p-type impurities, and the p-type impurities may be magnesium (Mg).

In some embodiments, the second conductivity-type semiconductor layer 140 may include an electron blocking layer, a low concentration p-type GaN layer, and a high concentration p-type GaN layer, stacked in a vertical direction (e.g., along the Z-direction). For example, the electron blocking layer may include a multi-layer in which a plurality of InₓAl_{y}Ga_{(1-x-y)}N (0≤x, y≤1, 0≤x+y≤1) layers having different compositions and each having a thickness of about 5 nm to about 100 nm are alternately stacked, or may include a single Al_{y}Ga_{(1-y)}N(0<y≤1) layer. The energy bandgap of the electron blocking layer may decrease as the distance from the active layer 130 increases. For example, the Al composition of the electron blocking layer may decrease as the distance from the active layer 130 increases.

In an embodiment, each of the plurality of second conductivity-type semiconductor layers 140 may be formed on the upper surface 130T of each of the plurality of active layers 130. In addition, the area of the upper surface 130T of each of the plurality of active layers 130 may be substantially the same as the area of the upper surface 140T of each of the plurality of second conductivity-type semiconductor layers 140. For example, referring to FIGS. 2A-2B, the upper surfaces of the rod 110R, the active layer 130, and the second conductivity-type semiconductor layer 140 may completely overlap each other in the vertical direction (e.g., as viewed in a top view), so sidewalls of the rod 110R, the active layer 130, and the second conductivity-type semiconductor layer 140 may be vertically aligned. In other words, the rod 110R, the active layer 130, and the second conductivity-type semiconductor layer 140 may form a single cylindrical column shape as a whole.

In an embodiment, the height level of the upper surface 140T of the second conductivity-type semiconductor layer 140 may be higher than the height level of the uppermost surface 120T of the insulating spacer 120 along the Z-direction relative to the bottom surface of the first conductivity-type semiconductor layer 110, e.g., the semiconductor layer 140 may extend above the insulating spacer 120. As such, a lower portion of the sidewall of the second conductivity-type semiconductor layer 140 may be in contact with the insulating spacer 120, and an upper portion of the sidewall of the second conductivity-type semiconductor layer 140 may be in contact with a second electrode layer 142 to be described below. In some embodiments, a length 140S (e.g., a height) in the vertical direction of the sidewall of the second conductivity-type semiconductor layer 140 contacting the insulating spacer 120 may be at least 50 nm.

Each of the plurality of light-emitting structures ES may be spaced apart from a neighboring light-emitting structure ES with the insulating spacer 120 therebetween. A separation distance between the plurality of light-emitting structures ES may be about 100 nm to about 2 μm.

Referring to FIG. 2A, a first electrode layer 112 may be disposed to be connected to the first conductivity-type semiconductor layer 110 in a groove GR passing through the active layer 130 and the second conductivity-type semiconductor layer 140. For example, as illustrated in FIG. 2A, the first electrode layer 112 may be directly on the first conductivity-type semiconductor layer 110. For example, the first electrode layer 112 may include Ag, Al, Ni, Cr, Au, Pt, Pd, Sn, W, Rh, Ir, Ru, Mg, Zn, Ti, Cu, or a combination thereof. In addition, the first electrode layer 112 may include a metal material having high reflectivity.

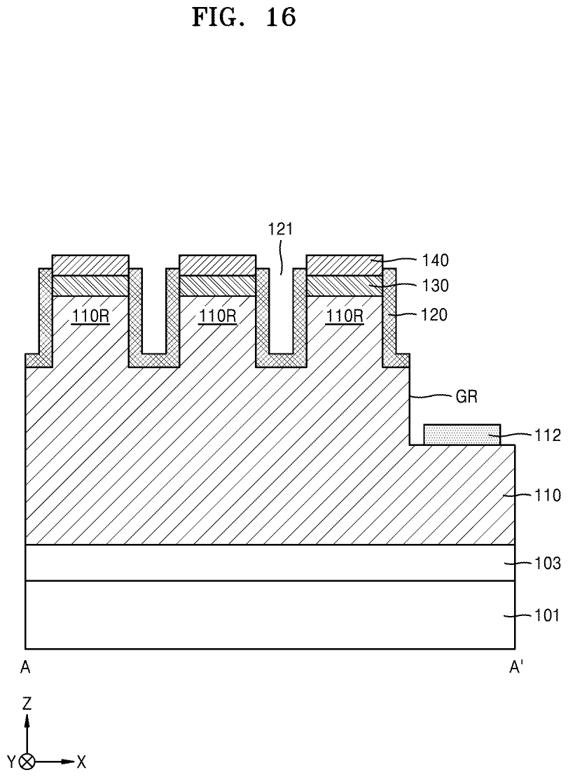

The second electrode layer 142 may fill an inner space 121 of the insulating spacer 120 (FIG. 16) and may be disposed to be connected to the plurality of second conductivity-type semiconductor layers 140. The second electrode layer 142 may be formed to be in, e.g., direct, contact with the upper surface of each of the plurality of second conductivity-type semiconductor layers 140 and a portion of the side surface of each of the plurality of second conductivity-type semiconductor layers 140. When viewed from a side cross-section, an upper surface 142T of the second electrode layer 142 may have a flat plate shape. In addition, the lower surface of the second electrode layer 142 may have a concave-convex shape, e.g., a shape including alternating protrusions and depressions. For example, referring to FIGS. 1 and 2A, a single second electrode layer 142 may, e.g., continuously, overlap (e.g., or cover) all the light-emitting structures ES. For example, as illustrated in FIG. 2A, the second electrode layer 142 may completely fill spaces between adjacent ones of the light-emitting structures ES, e.g., so the second electrode layer 142 may have a complementary shape with respect to the light-emitting structures ES and their arrangement. The second electrode layer 142 may include substantially the same material as a material constituting the first electrode layer 112.

In general, as the composition of indium (In) increases in quantum well layers composed of InₓGa₁₋ₓN (0≤x≤1) in a semiconductor light-emitting device, the wavelength of emitted light increases and the lattice constant of the quantum well layer also increases. Accordingly, compressive stress may be applied to the quantum well layer due to a difference in lattice constant generated between the quantum well layer and the quantum barrier layer. In addition, due to the characteristics of a gallium nitride (GaN) material formed by a high-temperature growth process, when a heterogeneous substrate, e.g., a sapphire substrate, is used, additional compressive stress may be applied to the quantum well layer.

The indium (In) composition of a semiconductor light-emitting device emitting a blue color wavelength is about 14% to about 17% of the entire quantum well layer, and a difference in lattice constant caused by the indium (In) composition of about 14% to about 17% does not significantly affect the efficiency characteristics of the semiconductor light-emitting device. On the other hand, when the indium (In) composition is increased to about 35% or more of the entire quantum well layer in order to realize a yellow color wavelength or a red color wavelength, a defect may occur due to a difference in lattice constant between a material constituting the quantum well layer and a material constituting the quantum barrier layer. In particular, in a quantum well layer for realizing a red color wavelength, the defect may be more prominent. The defect may act as a trap site for electrons and/or holes in the semiconductor light-emitting device and cause a problem of lowering the luminous efficiency of the semiconductor light-emitting device.

When compressive stress applied to the quantum well layer is removed from a heterogeneous substrate, e.g., a sapphire substrate, compressive stress generated by a high-concentration indium (In) composition may be relieved, thereby suppressing the occurrence of defects. Therefore, when the first conductivity-type semiconductor layer 110 is formed to have the plurality of rods 110R through a nano-patterning process, an upper region of the rods 110R may be in a state in which compressive stress generated by a substrate is relieved. As described above, when the quantum well layer is formed in the upper region of the rods 110R in which the compressive stress is relieved, defects may be suppressed from occurring.

Accordingly, in the semiconductor light-emitting device 10 according to an embodiment, compressive stress, which is applied to the quantum well layer from the substrate 101, may be relieved through the patterning of the first conductivity-type semiconductor layer 110, and light output may be improved by forming the plurality of active layers 130 as emission layers on the plurality of rods 110R in which the compressive stress is relieved through the patterning. Ultimately, in the semiconductor light-emitting device 10 according to an embodiment, the upper layer 110U of the first conductivity-type semiconductor layer 110 disposed under the active layer 130 may be selectively patterned to include the plurality of rods 110R, in order to relieve the compressive stress applied from the substrate 101, and thus, luminous efficiency may be improved, process efficiency may be increased, and product defects may be reduced.

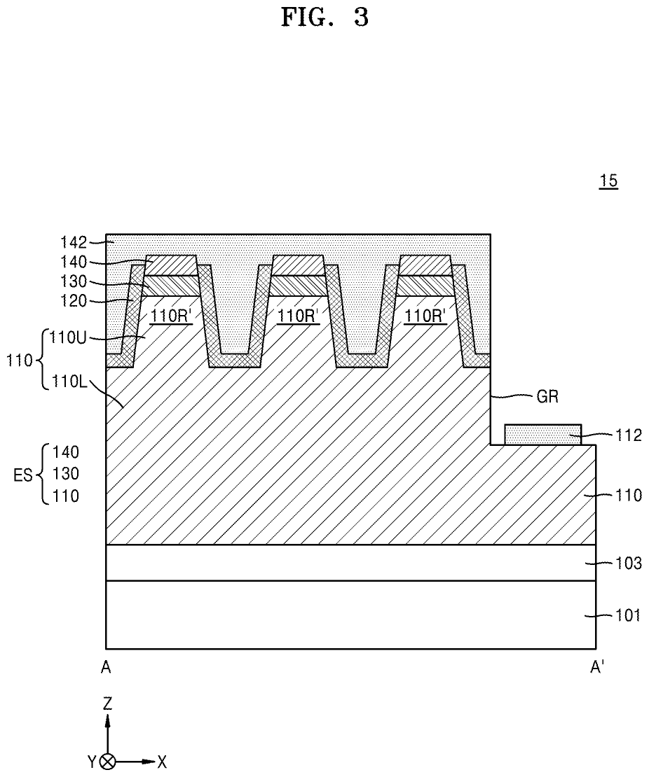

FIGS. 3 to 6 are views of semiconductor light-emitting devices 15, 20, 30, and 40 according to other embodiments. Most of the components constituting the semiconductor light-emitting devices 15, 20, 30, and 40 to be described below and materials constituting the components are substantially the same as or similar to those described above with reference to FIGS. 1 and 2A to 2C. Therefore, for convenience of description, differences relative to the semiconductor light-emitting device 10 described above will be mainly described.

Referring to FIG. 3, the semiconductor light-emitting device 15 formed on the substrate 101 and including the first conductivity-type semiconductor layer 110, the insulating spacer 120, the active layer 130, and the second conductivity-type semiconductor layer 140 is illustrated. In the semiconductor light-emitting device 15 according to the present embodiment, the first conductivity-type semiconductor layer 110 may be configured to include a plurality of rods 110R′.

In detail, the plurality of rods 110R′ may have inclined sidewalls rather than vertical sidewalls. In other words, the plurality of rods 110R′ may each have a trapezoidal vertical cross-section in a tapered shape. The trapezoidal cross-section of each of the plurality of rods 110R′ may be a feature that occurs during a dry etching process. In addition, the heights of the plurality of rods 110R′ may be about 100 nm to about 10 μm.

The insulating spacer 120 may be conformally disposed to cover the side surface of each of the plurality of rods 110R′. In addition, the insulating spacer 120 may be disposed to contact all sidewalls of the active layer 130 and portions of sidewalls of the second conductivity-type semiconductor layer 140. The insulating spacer 120 may be formed to have inclined sidewalls.

In this case, the active layer 130 and/or the second conductivity-type semiconductor layer 140 may also be formed to have inclined sidewalls, but is not limited thereto. In some embodiments, the insulating spacer 120 may completely fill a space between each two of the plurality of rods 110R′.

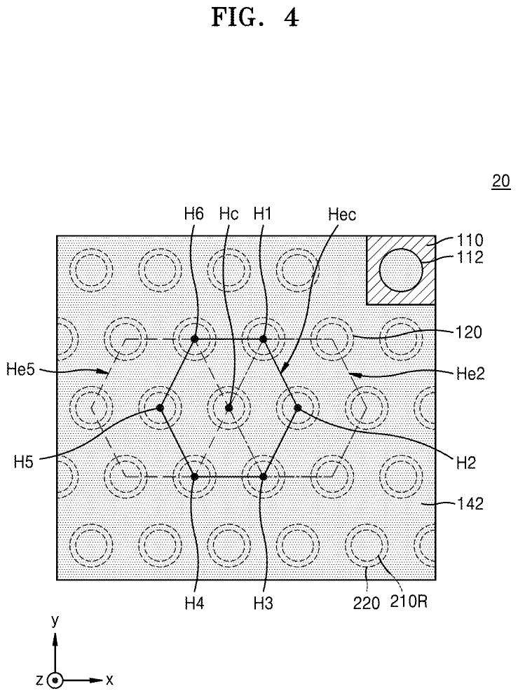

Referring to FIG. 4, the semiconductor light-emitting device 20 formed on the substrate 101 and including the first conductivity-type semiconductor layer 110, an insulating spacer 220, the active layer 130, and the second conductivity-type semiconductor layer 140 is illustrated. In the semiconductor light-emitting device 20 according to the present embodiment, a honeycomb structure may have a structure in which a plurality of rods 210R are disposed at vertices H1, H2, H3, H4, H5, and H6 of a hexagon and a central point Hc thereof. Also, as illustrated in FIG. 4, the plurality of rods 210R may be arranged in a continuous structure in which honeycomb structures overlap each other in a first direction (an X direction) and a second direction (a Y direction).

In detail, the plurality of rods 210R may be disposed in a structure in which the six vertices H1, H2, H3, H4, H5, and H6 of a central hexagon Hec illustrated by a solid line are central points of six hexagons disposed adjacently and the central point Hc of the central hexagon Hec is shared by the six hexagons. For example, the vertex H2 may be the central point of a second hexagon He2 illustrated by a dashed line, the vertex H5 may be the central point of a fifth hexagon He5 illustrated by a dashed line, and the central point Hc of the central hexagon Hec may be shared by the second hexagon He2 and the fifth hexagon He5 as one of six vertices of each of the second hexagon He2 and the fifth hexagon He5.

In this case, the hexagon in the honeycomb structure of the plurality of rods 210R may be a regular hexagon. In addition, all six triangles sharing the central point Hc of the central hexagon Hec may be equilateral triangles. Accordingly, in one hexagon, a distance between adjacent vertices or a distance between a vertex and a central point may be the same.

In the drawings, the plurality of rods 210R are illustrated as circular rods, but are not limited thereto. The insulating spacer 220 may be conformally disposed to cover the side surface of each of the plurality of rods 210R. In addition, the insulating spacer 220 may be disposed to contact all sidewalls of the active layer 130 and portions of sidewalls of the second conductivity-type semiconductor layer 140.

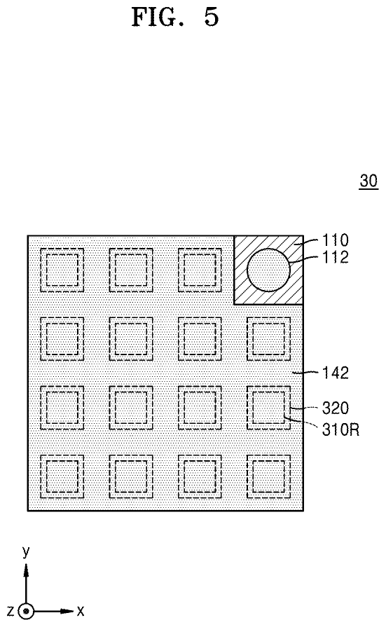

Referring to FIG. 5, the semiconductor light-emitting device 30 formed on the substrate 101 and including the first conductivity-type semiconductor layer 110, an insulating spacer 320, the active layer 130, and the second conductivity-type semiconductor layer 140 is illustrated. In the semiconductor light-emitting device 30 according to the present embodiment, the first conductivity-type semiconductor layer 110 may be configured to include a plurality of rods 310R.

For example, as illustrated in FIG. 5, the plurality of rods 310R may be quadrangular rods (e.g., having a quadrangular cross-section in a top view). When the plurality of rods 310R are quadrangular rods, the height of each of the plurality of rods 310R may be about 100 nm to about 10 μm, and the length of the diagonal of the upper surface of each of the plurality of rods 310R may be about 100 nm to about 10 μm.

The insulating spacer 320 may be conformally disposed to cover the side surface of each of the plurality of rods 310R. In addition, the insulating spacer 320 may be disposed to contact all sidewalls of the active layer 130 and portions of sidewalls of the second conductivity-type semiconductor layer 140.

For example, the thickness of the insulating spacer 320 may be about 50 nm to about 1 μm. In some embodiments, the insulating spacer 320 may completely fill a space between each two of the plurality of rods 310R.

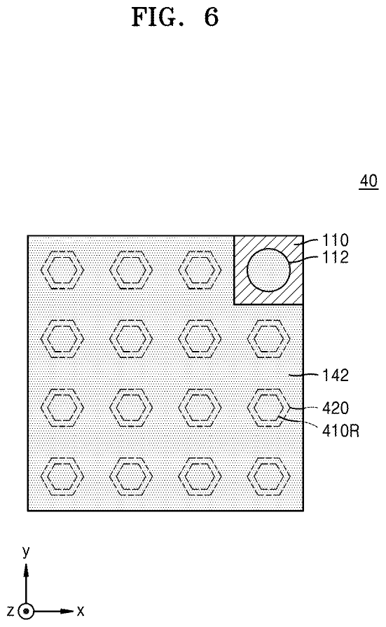

Referring to FIG. 6, the semiconductor light-emitting device 40 formed on the substrate 101 and including the first conductivity-type semiconductor layer 110, an insulating spacer 420, the active layer 130, and the second conductivity-type semiconductor layer 140 is illustrated. In the semiconductor light-emitting device 40 according to the present embodiment, the first conductivity-type semiconductor layer 110 may be configured to include a plurality of rods 410R.

For example, as illustrated in FIG. 6, the plurality of rods 410R may be hexagonal rods (e.g., having a hexagonal rod shape cross-section in a top view). When the plurality of rods 410R are hexagonal rods, the height of each of the plurality of rods 410R may be about 100 nm to about 10 μm, and the length of the diagonal of the upper surface of each of the plurality of rods 410R may be about 100 nm to about 10 μm.

The insulating spacer 420 may be conformally disposed to cover the side surface of each of the plurality of rods 410R. In addition, the insulating spacer 420 may be disposed to contact all sidewalls of the active layer 130 and portions of sidewalls of the second conductivity-type semiconductor layer 140.

For example, the thickness of the insulating spacer 420 may be about 50 nm to about 1 In some embodiments, the insulating spacer 420 may completely fill a space between each two of the plurality of rods 410R.

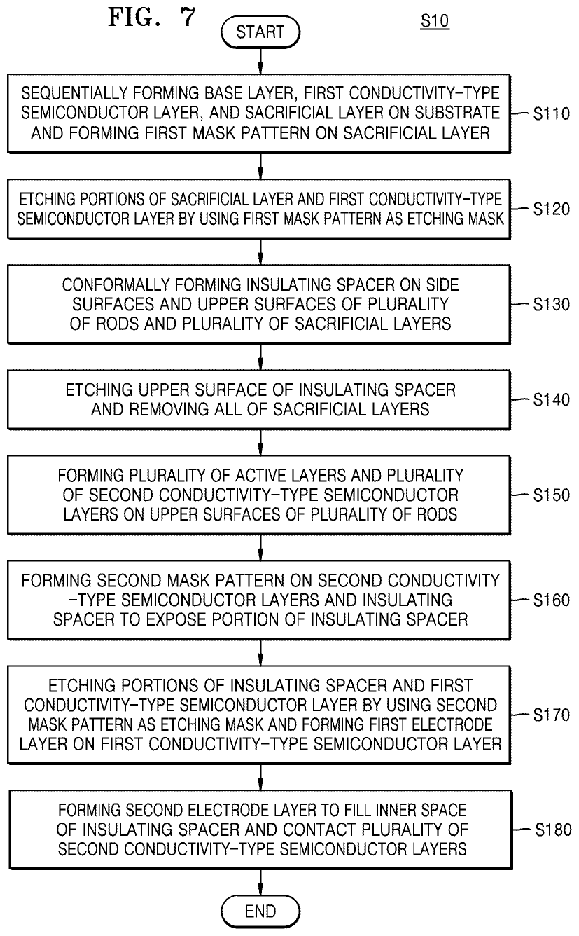

FIG. 7 is a flowchart of a method S10 of manufacturing a semiconductor light-emitting device, according to an embodiment.

Referring to FIG. 7, the method S10 of manufacturing a semiconductor light-emitting device, according to an embodiment, may include a process sequence of first to eighth operation S110 to S180. In cases where certain embodiments may be implemented otherwise, a specific process sequence may be performed different from the process sequence to be described. For example, two processes described in succession may be performed substantially simultaneously, or may be performed in an order opposite to the described order.

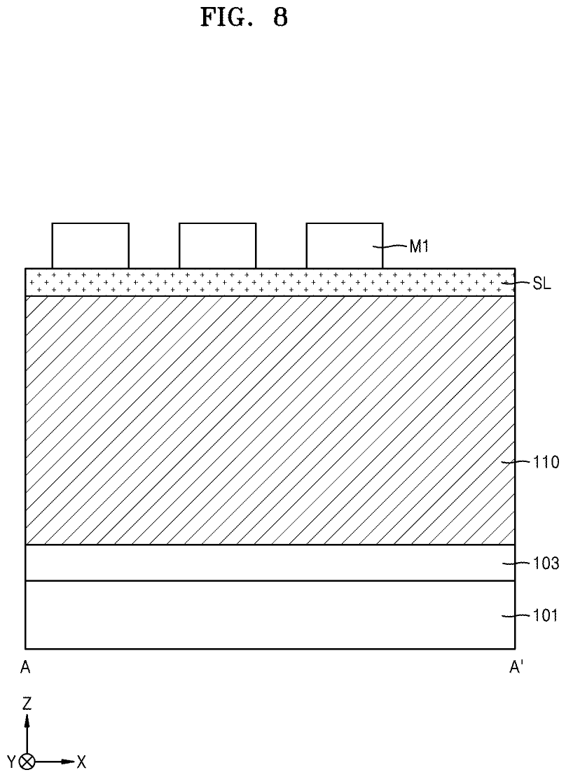

The method S10 of manufacturing a semiconductor light-emitting device, according to an embodiment, may include a first operation S110 of sequentially forming a base layer, a first conductivity-type semiconductor layer, and a sacrificial layer on a substrate and forming a first mask pattern on the sacrificial layer, a second operation S120 of etching portions of the sacrificial layer and the first conductivity-type semiconductor layer by using the first mask pattern as an etching mask, a third operation S130 of conformally forming an insulating spacer on side surfaces and upper surfaces of a plurality of rods and a plurality of sacrificial layers, a fourth operation S140 of etching an upper surface of the insulating spacer and removing all of the plurality of sacrificial layers, a fifth operation S150 of forming a plurality of active layers and a plurality of second conductivity-type semiconductor layers on upper surfaces of the plurality of rods, a sixth operation S160 of forming a second mask pattern on the plurality of second conductivity-type semiconductor layers and the insulating spacer to expose a portion of the insulating spacer, a seventh operation S170 of etching portions of the insulating spacer and the first conductivity-type semiconductor layer by using the second mask pattern as an etching mask and forming a first electrode layer on the first conductivity-type semiconductor layer, and an eighth operation S180 of forming a second electrode layer to fill an inner space of the insulating spacer and contact the plurality of second conductivity-type semiconductor layers. The technical characteristics of each of the first to eighth operations S110 to S180 will be described in detail with reference to FIGS. 8 to 16 to be described below.

FIGS. 8 to 16 are cross-sectional views of stages in a method of manufacturing a semiconductor light-emitting device, according to an embodiment.

Referring to FIG. 8, the base layer 103, the first conductivity-type semiconductor layer 110, and a sacrificial layer SL may be sequentially formed on the substrate 101, and a first mask pattern M1 may be formed on the sacrificial layer SL.

The substrate 101 may have light-transmitting properties. The substrate 101 may include a light-transmitting material, or a material capable of having light-transmitting properties when formed to a certain thickness or less. The substrate 101 may be an insulating, conductive, or semiconductor substrate. For example, the substrate 101 may include at least one of Al₂O₃, GaN, Si, Ge, GaAs, ZnO, SiGe, SiC, Ga₂O₃, LiGaO₂, LiAlO₂, MgAl₂O₄, or the like.

The base layer 103 may be formed to provide a growth surface for the first conductivity-type semiconductor layer 110. For example, the base layer 103 may include InₓAl_{y}Ga_{(1-x-y)}(0≤x≤1, 0≤y≤1), GaN, AlN, AlGaN, InGaN, InGaNAlN, or the like. If necessary, a material, e.g., ZrB₂, HfB₂, ZrN, HfN, or TiN, may be used for the base layer 103. In addition, the base layer 103 may be formed to have a multi-layered structure or may be used by gradually changing the composition thereof. In some embodiments, the base layer 103 may be omitted.

The first conductivity-type semiconductor layer 110 may have a single-layer structure, or may have a multi-layer structure having different compositions. For example, the first conductivity-type semiconductor layer 110 may include a carrier injection layer capable of improving electron and hole injection efficiency, and may also have various types of superlattice structures.

The first conductivity-type semiconductor layer 110 may further include a current diffusion layer in its upper region. The current diffusion layer may have a structure in which a plurality of InₓAl_{y}Ga_{(1-x-y)}N (0≤x, y≤1, 0≤x+y≤1) layers having different compositions or different impurity contents are repeatedly stacked or an insulating material layer is partially formed.

The sacrificial layer SL is formed on the first conductivity-type semiconductor layer 110. For example, the sacrificial layer SL may include a material, e.g., Tetra-Ethyl OrthoSilicate (TEOS), Boron Phosphorous Silicate Glass (BPSG), Phosphorous Silicate Glass (PSG), Undoped Silicate Glass (USG), Spin On Glass (SOG), High Density Plasma oxide (HDP), Silicon Oxide (SiO₂), Silicon Nitride (SiₓN_{y}), or Indium Tin Oxide (ITO). The sacrificial layer SL may be formed to have a thickness of about 50 nm to about 10 μm.

The first mask pattern M1 is formed on the sacrificial layer SL. When a photoresist is exposed and developed after the photoresist is coated on the sacrificial layer SL, only a portion of the photoresist remains and the rest is removed, and thus, the first mask pattern M1 is formed as illustrated in FIG. 8. Alternatively, the first mask pattern M1 is formed through a nano imprint method.

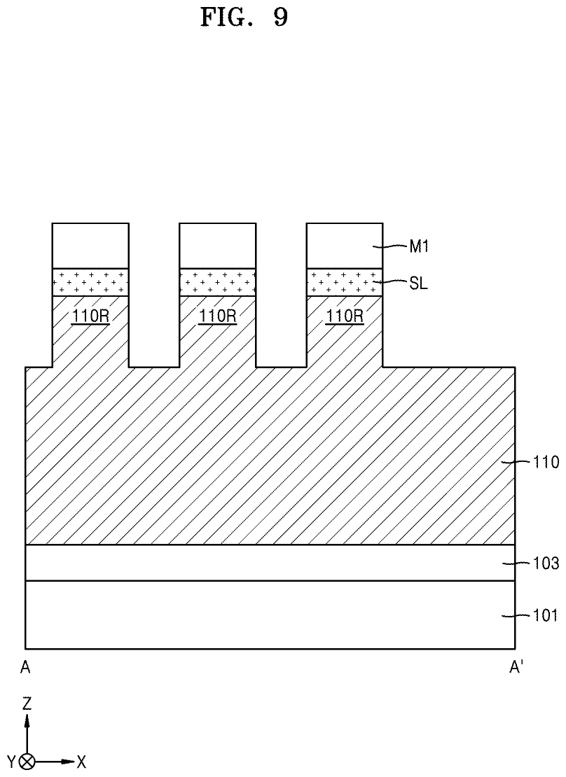

The first mask pattern M1 may be a pattern arranged with a certain rule or an irregularly arranged pattern. In addition, the shape and width of the first mask pattern M1 may be adjusted to affect the shapes of the plurality of rods 110R (refer to FIG. 9) included in the first conductivity-type semiconductor layer 110 in a subsequent process.

Referring to FIG. 9, portions of the sacrificial layer SL and the first conductivity-type semiconductor layer 110 are etched using the first mask pattern M1 as an etching mask, and the first mask pattern M1 is removed, e.g., by an ashing and stripping process. That is, an upper portion of the first conductivity-type semiconductor layer 110 (i.e., the upper layer 110U of FIG. 2A) may be selectively patterned, e.g., etched, to form the rods 110R on a lower portion of the first conductivity-type semiconductor layer 110 (i.e., on the lower layer 110L of FIG. 2A).

The etching process may be a dry etching process. Through the dry etching process, the first conductivity-type semiconductor layer 110 including the plurality of rods 110R is formed. Although the drawings show that the plurality of rods 110R have vertical sidewalls, due to the characteristics of the dry etching process, the plurality of rods 110R may have tapered sidewalls that widen downward rather than vertical sidewalls.

The sacrificial layer SL partially exposes a lower layer of the first conductivity-type semiconductor layer 110. When viewed from the top, the plurality of rods 110R and the sacrificial layer SL formed on the upper surfaces thereof may each have a circular shape, e.g., the shape may be determined by the shape of the first mask pattern M1. That is, each of the plurality of rods 110R may be formed to have a circular rod shape.

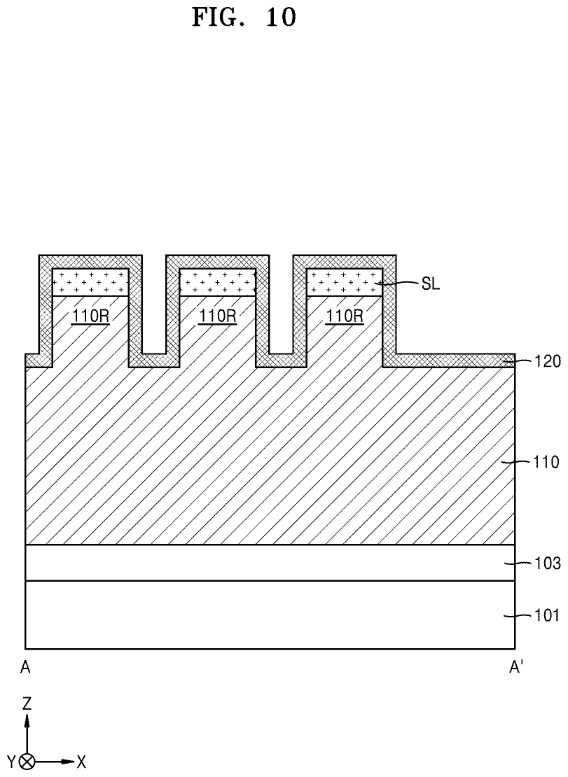

Referring to FIG. 10, the insulating spacer 120 is conformally formed on side surfaces and upper surfaces of the plurality of rods 110R and the sacrificial layer SL formed on the upper surfaces thereof. The insulating spacer 120 may be formed by an atomic layer deposition (ALD) method, and may have a thickness of about 50 nm to about 1 μm.

Through the ALD method having excellent step coverage, the insulating spacer 120 may be formed to have a uniform thickness. The insulating spacer 120 may include, e.g., silicon oxide, silicon oxynitride, silicon nitride, or aluminum oxide.

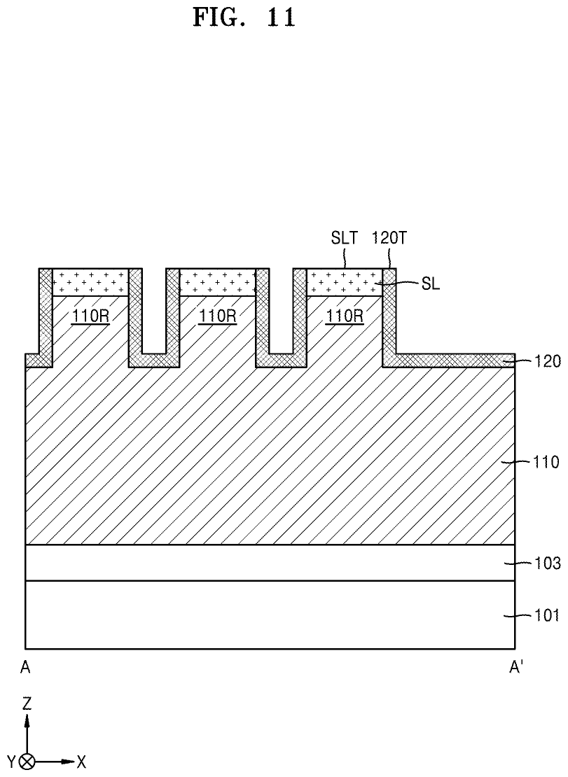

Referring to FIG. 11, the upper surface of the insulating spacer 120 is etched to expose the upper surface of the sacrificial layer SL.

A portion of the insulating spacer 120 positioned on the sacrificial layer SL may be etched. The sacrificial layer SL and the insulating spacer 120 may respectively include materials having different etch selectivity. Accordingly, while the upper surface of the insulating spacer 120 is being etched, the sacrificial layer SL may function as an etch stop layer. Due to the etching process, the vertical level of an upper surface SLT of the sacrificial layer SL and the vertical level of an upper surface 120T of the insulating spacer 120 may be substantially the same.

Also, as described above, the upper outer wall of the insulating spacer 120 may be a vertical sidewall or a round sidewall. This may be a feature that depends on the degree of etching in the process of forming the insulating spacer 120. That is, because the upper outer wall of the insulating spacer 120 protrudes compared to other portions, e.g., the insulating spacer 120 may be a most external layer on the structure of FIG. 10, more etching may be performed on the upper outer wall of the insulating spacer 120, e.g., on an upper edge of the outer wall of the insulating spacer 120. In this case, the upper outer wall of the insulating spacer 120 may have a round sidewall shape.

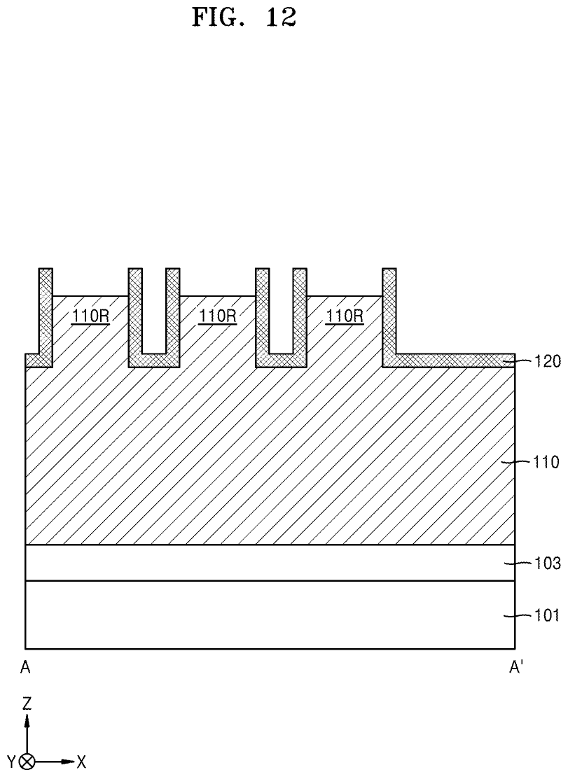

Referring to FIG. 12, the sacrificial layer SL (refer to FIG. 11) is entirely removed through an etching process. The etching process for removing the sacrificial layer SL may be performed by a wet etching process using an etching solution. The etching solution for the wet etching may remove only the sacrificial layer SL while minimizing an effect on a material constituting the insulating spacer 120 and a material constituting the first conductivity-type semiconductor layer 110.

During the wet etching process, the insulating spacer 120 is maintained without being etched to perform a function of firmly fixing and supporting the plurality of rods 110R so that the plurality of rods 110R do not collapse or break. In addition, the insulating spacer 120 may prevent the etching solution from penetrating under the plurality of rods 110R.

Also, the insulating spacer 120 may be a mask layer exposing the upper surfaces of the plurality of rods 110R. In other words, the insulating spacer 120 may function as a mask layer that provides a space for forming the active layer 130 and the second conductivity-type semiconductor layer 140, formed (or grown) in a subsequent process. Also, as described above, the upper outer wall of the insulating spacer 120 may be a vertical sidewall or a round sidewall.

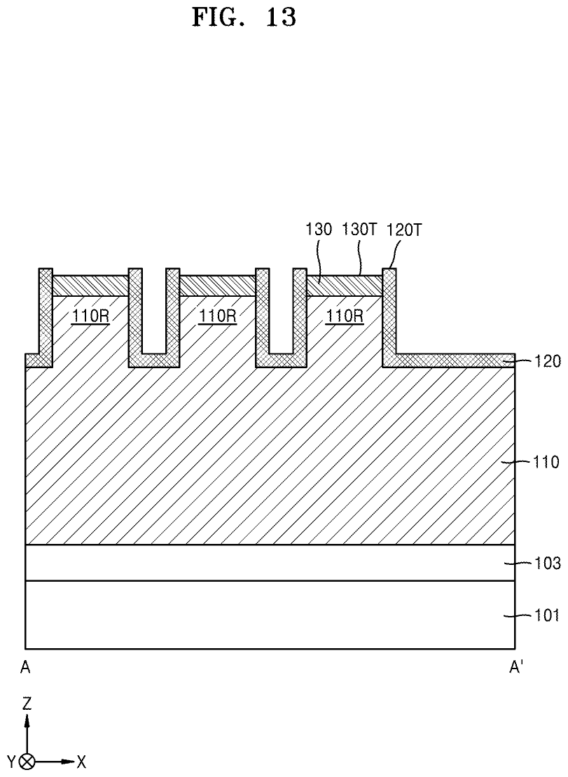

Referring to FIG. 13, a plurality of the active layers 130 are respectively formed, e.g., grown, on the upper surfaces of the plurality of rods 110R.

Each of the active layers 130 may have an MQW structure in which quantum well layers and quantum barrier layers are alternately stacked. For example, each of the quantum well layers and each of the quantum barrier layers may include InₓAl_{y}Ga_{(1-x-y)}N (0≤x, y≤1, 0≤x+y≤1) having different compositions. The quantum well layer may include InₓGa₁₋ₓN (0≤x≤1), and the quantum barrier layer may include GaN or InₓAl_{y}Ga_{(1-x-y)}N (0≤x, y≤1, 0≤x+y≤1). The thickness of the quantum well layer and the thickness of the quantum barrier layer may each range from about 1 nm to about 50 nm. The active layer 130 is not limited to the MQW structure and may have, e.g., a single quantum well structure.

In an embodiment, the level of an upper surface 130T of each of the plurality of active layers 130 may be vertically lower than the level of an uppermost surface 120T of the insulating spacer 120. In addition, the area of the upper surface 130T of each of the plurality of active layers 130 may be substantially the same as the area of the upper surface of each of the plurality of rods 110R.

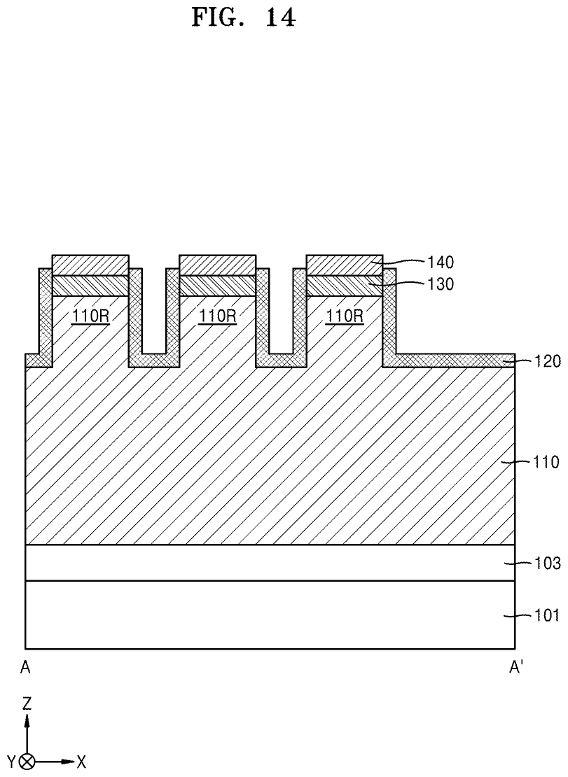

Referring to FIG. 14, a plurality of second conductivity-type semiconductor layers 140 are respectively formed, e.g., grown, on the upper surfaces 130T of the plurality of active layers 130.

Each of the second conductivity-type semiconductor layers 140 may be a nitride semiconductor layer having a composition of p-type InₓAl_{y}Ga_{(1-x-y)}N (0≤x<1, 0≤y<1, 0≤x+y<1). For example, the second conductivity-type semiconductor layer 140 may include p-type impurities, and the p-type impurities may be magnesium (Mg).

In an embodiment, the area of the upper surface 130T of each of the plurality of active layers 130 may be substantially the same as the area of the upper surface of each of the plurality of second conductivity-type semiconductor layers 140. In other words, as illustrated in the drawings, the rod 110R, the active layer 130, and the second conductivity-type semiconductor layer 140 may form a single cylindrical shape as a whole.

In an embodiment, a portion of the sidewall of the second conductivity-type semiconductor layer 140 may be in contact with the insulating spacer 120. In some embodiments, a length in a vertical direction of the sidewall of the second conductivity-type semiconductor layer 140 contacting the insulating spacer 120 may be at least 50 nm.

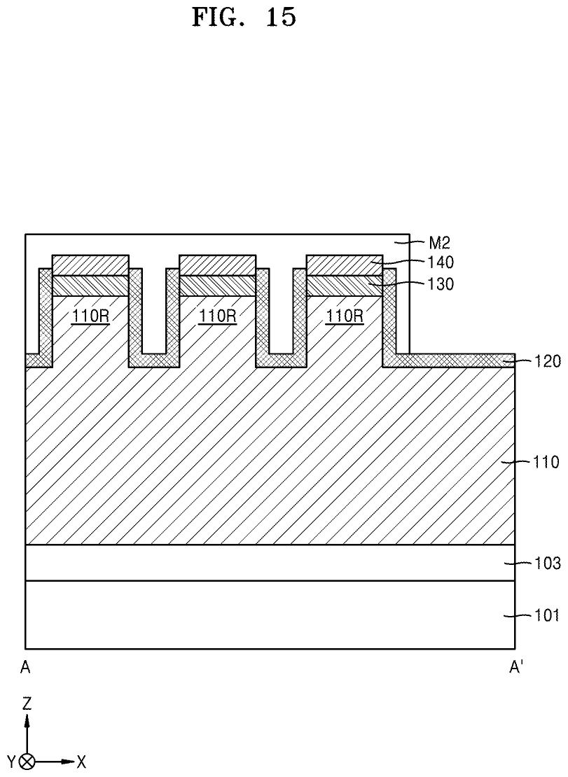

Referring to FIG. 15, a second mask pattern M2 is formed on the second conductivity-type semiconductor layer 140 and the insulating spacer 120 to expose a portion of the insulating spacer 120.

The second mask pattern M2 is formed on the second conductivity-type semiconductor layer 140 and the insulating spacer 120 to cover all of the plurality of rods 110R. When a photoresist is coated on the second conductivity-type semiconductor layer 140 and the insulating spacer 120, and then is exposed and developed, only a portion of the photoresist remains and the rest is removed. Thus, the second mask pattern M2 is formed as illustrated in FIG. 15.

Referring to FIG. 16, portions of the insulating spacer 120 and the first conductivity-type semiconductor layer 110 are etched using the second mask pattern M2 as an etching mask, the second mask pattern M2 is removed, and the first electrode layer 112 is formed on an exposed portion of the first conductivity-type semiconductor layer 110. When the second mask pattern M2 is removed, the inner space 121 of the insulating spacer 120, e.g., an empty space on (or surrounded by) the insulating spacer 120 between adjacent ones of the rods 110R, may be exposed. For example, as illustrated in FIG. 16, the inner space 121 may fill, e.g., be inside, the U-shaped cross-section of the insulating spacer 120.

The etching process may be a dry etching process. Through the dry etching process, the first conductivity-type semiconductor layer 110 is formed to include a region in which the first electrode layer 112 is disposed. That is, the groove GR partially exposing a lower layer of the first conductivity-type semiconductor layer 110 is formed.

The first electrode layer 112 may be disposed to be connected to the first conductivity-type semiconductor layer 110 in the groove GR passing through the active layer 130 and the second conductivity-type semiconductor layer 140. The first electrode layer 112 may include, e.g., at least one of Ag, Al, Ni, Cr, Au, Pt, Pd, Sn, W, Rh, Ir, Ru, Mg, Zn, Ti, Cu, and a combination thereof. Also, the first electrode layer 112 may include a metal material having high reflectivity.

Referring back to FIG. 2A, the second electrode layer 142 may be formed to fill the inner space 121 of the insulating spacer 120 and be connected to the plurality of second conductivity-type semiconductor layers 140. Also, as described above, the upper outer wall of the insulating spacer 120 may be a vertical sidewall or a round sidewall.

The second electrode layer 142 may be formed to be in contact with the upper surface of each of the plurality of second conductivity-type semiconductor layers 140 and a portion of the side surface of each of the plurality of second conductivity-type semiconductor layers 140. When viewed from a side cross-section, the second electrode layer 142 may be formed to have a concave-convex shape. The second electrode layer 142 may include, e.g., at least one of Ag, Al, Ni, Cr, Au, Pt, Pd, Sn, W, Rh, Ir, Ru, Mg, Zn, Ti, Cu, and a combination thereof. In addition, the second electrode layer 142 may include a metal material having high reflectivity.

In this way, the semiconductor light-emitting device 10 according to an embodiment may be manufactured. Ultimately, according to the method of manufacturing the semiconductor light-emitting device 10, according to an embodiment, the upper layer 110U of the first conductivity-type semiconductor layer 110 disposed under the active layer 130 may be selectively patterned to relieve compressive stress applied from the substrate 101, and thus, luminous efficiency may be improved, process efficiency may be increased, and product defects may be reduced.

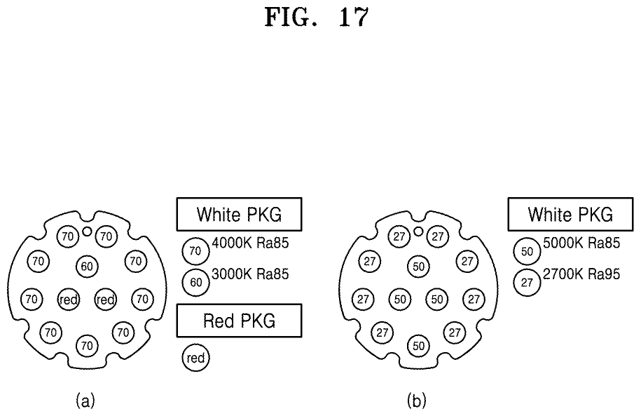

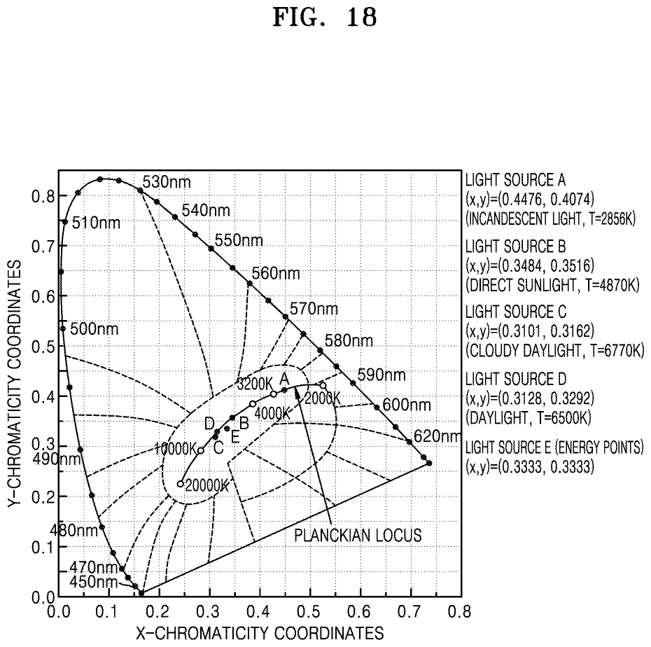

FIG. 17 is a schematic cross-sectional view of a white light source module employable in a lighting apparatus as a semiconductor light-emitting device according to an embodiment, and FIG. 18 is a CIE chromaticity diagram illustrating a perfect radiator spectrum that is usable for a semiconductor light-emitting device according to an embodiment.

Specifically, each of the light source modules illustrated in parts (a) and (b) of FIG. 17 may include a plurality of light-emitting device packages 60, 70 (White PKG), red (Red PKG), 27, and 50 mounted on a circuit board. The light-emitting device packages 60, 70, red, 27, and 50 may be the light-emitting devices 10 and 20 manufactured by the method of manufacturing a light-emitting device, according to an embodiment. A plurality of light-emitting device packages mounted on one light source module may be the same type of packages that generate light having the same wavelength. However, as in the present embodiment, the plurality of light-emitting device packages may be different types of packages that generate light having different wavelengths.

Referring to part (a) of FIG. 17, the white light source module may be configured by combining white light-emitting device packages 60 and 70 having color temperatures of about 3,000K and about 4,000K with a red light-emitting device package red. The white light source module may provide white light having a color temperature of about 3,000K to about 4,000K and a color rendering index (CRI) Ra of about 85 to about 100.

In another embodiment, the white light source module may include only a white light-emitting device package, but some packages may provide white light having different color temperatures. For example, as illustrated in part (b) of FIG. 17, white light having a color temperature of about 2,700K to about 5,000K and a CRI Ra of about 85 to about 99 may be provided by combining a white light-emitting device package 27 having a color temperature of about 2,700K with a white light-emitting device package 50 having a color temperature of about 5,000K. In this case, the number of light-emitting device packages for each color temperature may vary mainly according to a basic color temperature setting value. For example, in a lighting apparatus, of which a basic color temperature setting value is around a color temperature of about 4,000K, the number of packages corresponding to a color temperature of about 4,000K may be greater than the number of packages corresponding to a color temperature of about 3,000K or the number of red light-emitting device packages.

In this way, the different types of light-emitting device packages may be configured to include at least one of a light-emitting device emitting white light by combining a yellow, green, red, and orange-color phosphor in a blue light-emitting device, and a violet, blue, green, red, and infrared light-emitting device and adjust a color temperature and a CRI of the white light.

In a single light-emitting device package, light having a desired color may be determined according to the wavelength of a light-emitting diode (LED) chip, which is a light-emitting device, and the type and mixing ratio of phosphors. In the case of white light, the color temperature and the CRI may be adjusted.

For example, when the LED chip emits blue light, a light-emitting device package including at least one of the yellow, green, and red phosphors may be configured to emit white light having various color temperatures according to a mixing ratio of the phosphors. Unlike this, the light-emitting device package, in which the green or red phosphor is applied to a blue LED chip, may be configured to emit green or red light. The color temperature and the CRI of the white light may be adjusted by combining the light-emitting device package emitting the white light and the light-emitting device package emitting the green or red light. In addition, the light-emitting device package may include at least one of light-emitting devices emitting the violet, blue, green, red, and infrared light.

In this case, the lighting apparatus may adjust the CRI to a photovoltaic level in a sodium (Na) lamp. In addition, the lighting apparatus may generate a variety of white light having a color temperature of about 1,500K to about 20,000K. When necessary, the lighting apparatus may adjust an illumination color according to a surrounding atmosphere or a mood by generating infrared light or visible light, e.g., violet, blue, green, red, or orange color light. In addition, the lighting apparatus may generate light having a specific wavelength so as to promote the growth of plants.

The white light, which is generated by the combination of the yellow, green and red phosphors and/or the green and red light-emitting devices in the blue light-emitting diode has two or more peak wavelengths. As illustrated in FIG. 18, (x, y) coordinates of the white light in the CIE 1931 coordinate system may be positioned within a line segment connecting coordinates (0.4476, 0.4074), (0.3484, 0.3516), (0.3101, 0.3162), (0.3128, 0.3292), and (0.3333, 0.3333). Alternatively, the (x, y) coordinates may be positioned in a region surrounded by the line segment and a black-body radiator spectrum. The color temperature of the white light is in the range of about 1,500K to about 20,000K. In FIG. 18, because the white light around point E (0.3333, 0.3333) under the black-body radiator spectrum (Planckian locus) is relatively weak in the light of the yellow-based component, it may be used as an illumination light source in a region in which a user may have a more vivid or fresh feeling than the naked eyes. Therefore, an illumination product using the white light around point E (0.3333, 0.3333) under the black-body radiator spectrum (Planckian locus) may be suitable as lighting for shopping malls that sell groceries and clothes.

Various materials, e.g., phosphors and/or quantum dots, may be used as a material for converting a wavelength of light emitted by the semiconductor light-emitting diode. The phosphor may have the following empirical formulas and colors.

Oxide-based: yellow and green color Y₃Al₅O₁₂:Ce, Tb₃Al₅O₁₂:Ce, Lu₃Al₅O₁₂:Ce

Silicate-based: yellow color and green color (Ba,Sr)₂SiO₄:Eu, yellow color and orange color (Ba,Sr)₃SiO₅:Ce

Nitride-based: green color β-SiAlON:Eu, yellow color La₃Si₆O₁₁:Ce, orange color α-SiAlON:Eu, red color CaAlSiN₃:Eu, Sr₂Si₅N₈:Eu, SrSiAl₄N₇:Eu, SrLiAl₃N₄:Eu, Ln₄₋ₓ(Eu_{z}M_{1-z})ₓSi_{12-y}Al_{y}O_{3+x+y}N_{18-x-y} (0.5≤x≤3, 0<z<0.3, 0<y≤4)—Formula (1). In Formula (1), Ln may be at least one element of group Ma elements and rare-earth elements, and M may be at least one element of calcium (Ca), barium (Ba), strontium (Sr), and magnesium (Mg).

Fluoride-based: KSF-based red color K₂SiF₆:Mn₄⁺, K₂TiF₆:Mn₄⁺, NaYF₄:Mn₄⁺, NaGdF₄:Mn₄⁺, K₃SiF₇:Mn₄⁺.

The composition of the phosphor needs to basically conform with stoichiometry, and the respective elements may be substituted by other elements included in the respective groups of the periodic table. For example, Sr may be substituted by at least one of barium (Ba), Ca, and Mg of alkaline-earth group II, and Y may be substituted by at least one of terbium (Tb), lutetium (Lu), scandium (Sc), and gadolinium (Gd). In addition, europium (Eu), which is an activator, may be substituted by at least one of cerium (Ce), terbium (Tb), praseodymium (Pr), erbium (Er), and ytterbium (Yb) according to a desired energy level. The activator may be applied solely or a sub activator may be additionally applied for characteristic modification.

In particular, in order to improve the reliability at high temperature and high humidity, the fluoride-based red phosphor may be coated with a Mn-free fluoride material or may further include an organic coating on the surface of the phosphor or the coated surface of the Mn-free fluoride material. In the case of the fluoride-based red phosphor, it is possible to implement a narrow half-width of about 40 nm or less unlike other phosphors. Therefore, the fluoride-based red phosphor may be applied to a high-resolution TV, e.g., UHD TV. In addition, a wavelength conversion unit may include wavelength conversion materials, e.g., quantum dots, by substituting phosphors or combining phosphors.

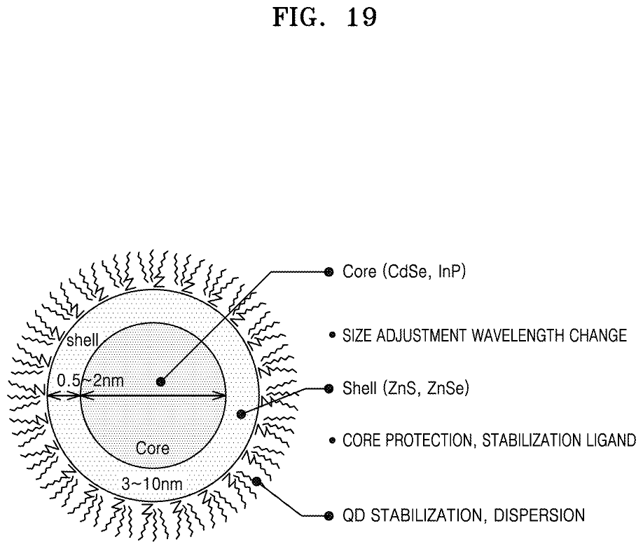

FIG. 19 is a schematic view of a cross-sectional structure of a quantum dot (QD), which may be used as a wavelength conversion material for a semiconductor light-emitting device according to an embodiment.

For example, the QD may have a core-shell structure using group III-V or II-VI compound semiconductors. For example, the QD may have a core, e.g., CdSe or InP, and a shell, e.g., ZnS or ZnSe. In addition, the QD may include a ligand for stabilizing the core and the shell. For example, the core may have a diameter of about 1 nm to about 30 nm, e.g., about 3 nm to about 10 nm. The shell may have a thickness of about 0.1 nm to about 20 nm, e.g., about 0.5 nm to about 2 nm.

The QD may implement various colors according to a size. In particular, when the QD is used as a phosphor substitute, the QD may be used as a red or green phosphor. In the case of using the QD, a narrow half-width (for example, about 35 nm) may be implemented.

The wavelength conversion material may be implemented as being contained in an encapsulating material. However, the wavelength conversion material may be previously prepared in a film shape and be attached to a surface of an optical structure, e.g., an LED chip or a light guide plate. In this case, the wavelength conversion material may be easily applied to a desired region in a structure having a uniform thickness.

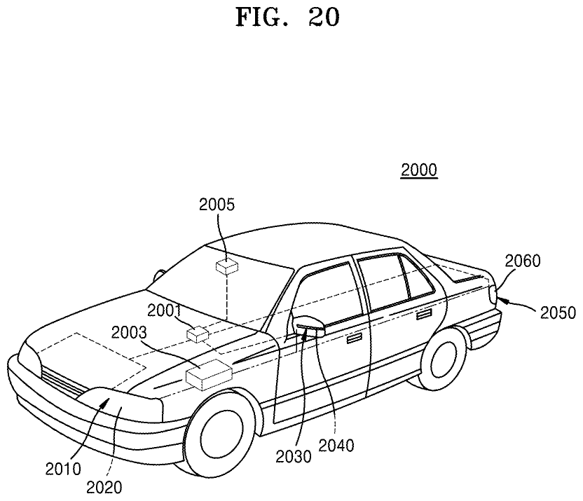

FIG. 20 is a perspective view of a vehicle 2000 including a semiconductor light-emitting device according to an embodiment.

Although an automobile is illustrated as the vehicle 2000 in FIG. 20, embodiments are not limited thereto. The vehicle 2000 may include a land vehicle, e.g., a bicycle, a tricycle, a passenger car, a caterpillar tractor, a train, or a tram, a marine vehicle, e.g., a ship, a boat, or a submarine, and an air vehicle, e.g., a plane or a helicopter, and the like.

Referring to FIG. 20, a headlamp module 2020 may be installed in a headlamp unit 2010 of the vehicle 2000. A side mirror lamp module 2040 may be installed in an outer side mirror unit 2030, and a tail lamp module 2060 may be installed in a tail lamp unit 2050.

The headlamp module 2020 may be a light source module including the semiconductor light-emitting devices 10, 15, 20, 30, and 40, described above, alone or in combination.

A power supply 2003 embedded in the vehicle 2000 may supply power to each of the headlamp module 2020, the side mirror lamp module 2040, and the tail lamp module 2060. In addition, a controller 2001 embedded in the vehicle 2000 may be configured to control operations including on/off operations of the headlamp module 2020, the side mirror lamp module 2040, and the tail lamp module 2060.

The controller 2001 may be a driving semiconductor chip that individually or collectively, e.g., jointly, drives at least one of the semiconductor light-emitting devices 10, 15, 20, 30, and 40 described above, and may be electrically connected to a driving semiconductor chip and configured to control the driving semiconductor chip.

The vehicle 2000 may further include a vision recognition apparatus 2005. The vision recognition apparatus 2005 may be configured to detect an object in front and a movement thereof. The vision recognition apparatus 2005 may include a camera that may receive a front view and convert the received front view into digital data, a processor that identifies, by using the digital data, a position where light emitted from the headlamp module 2020 should be irradiated and a position where the light should not be irradiated, and an output apparatus that transmits a result processed by the processor to the controller 2001.

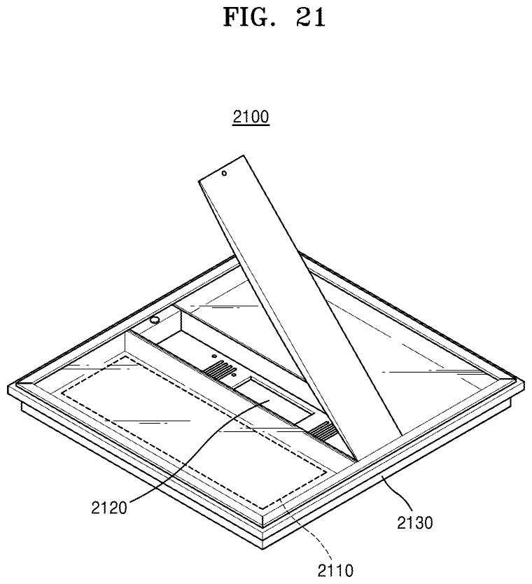

FIG. 21 is a perspective view of a flat-panel lighting apparatus 2100 including a semiconductor light-emitting device according to an embodiment.

Referring to FIG. 21, the flat-panel lighting apparatus 2100 may include a light source module 2110, a power supply 2120, and a housing 2130.

The light source module 2110 may include a light-emitting device array as a light source. The light source module 2110 may include at least one of the semiconductor light-emitting devices 10, 15, 20, 30, and 40 as a light source. The light source module 2110 may be formed to have a flat shape as a whole.

The power supply 2120 may be configured to supply power to the light source module 2110. The housing 2130 may have an accommodating space to accommodate the light source module 2110 and the power supply 2120 therein, and may be formed to have a hexahedral shape with one open side. The light source module 2110 may be disposed to emit light toward the open side of the housing 2130.

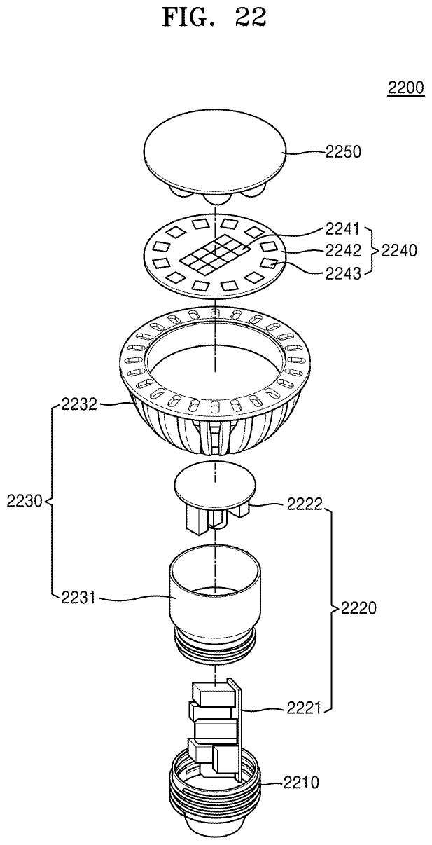

FIG. 22 is an exploded perspective view of a lighting apparatus including a semiconductor light-emitting device according to an embodiment.

Referring to FIG. 22, a lighting apparatus 2200 may include a socket 2210, a power supply 2220, a heat sink 2230, a light source module 2240, and an optical unit 2250.

The socket 2210 may be configured to be replaceable with an existing lighting apparatus. Power may be supplied to the lighting apparatus 2200 through the socket 2210. The power supply 2220 may be disassembled into a first power supply 2221 and a second power supply 2222. The heat sink 2230 may include an internal heat sink 2231 and an external heat sink 2232. The internal heat sink 2231 may be directly connected to the light source module 2240 and/or the power supply 2220, and thus, heat may be transferred to the external heat sink 2232.

The light source module 2240 may receive power from the power supply 2220 and emit light to the optical unit 2250. The light source module 2240 may include a light-emitting device package 2241, a circuit board 2242, and a controller 2243, and the controller 2243 may store driving information of the light-emitting device package 2241. The light-emitting device package 2241 may include at least one of the semiconductor light-emitting devices 10, 15, 20, 30, and 40, described above, as a light source. The optical unit 2250 may include an internal optical unit and an external optical unit, and may be configured to evenly distribute light emitted by the light source module 2240.

By way of summation and review, embodiments provide a semiconductor light-emitting device with a patterned first conductivity type semiconductor layer, e.g., including a plurality of rods spaced apart from each other, under an active layer to relieve stress applied from a substrate. Embodiments also provide a method of manufacturing a semiconductor light-emitting device with improved luminous efficiency by selectively etching a first conductive type semiconductor layer under an active layer to relieve stress applied from a substrate.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor light-emitting device, comprising:
a first conductivity-type semiconductor layer including a lower portion and an upper portion on the lower portion, the upper portion including rods spaced apart from each other;
active layers on upper surfaces of the rods, respectively;
second conductivity-type semiconductor layers on upper surfaces of the active layers, respectively;
an insulating spacer extending conformally between the rods, the insulating spacer surrounding all sidewalls of each of the active layers, and covering portions of sidewalls of each of the second conductivity-type semiconductor layers;
a first electrode layer in contact with the lower portion of the first conductivity-type semiconductor layer; and
a second electrode layer filling an inner space of the insulating spacer and in contact with the second conductivity-type semiconductor layers.

2. The semiconductor light-emitting device as claimed in claim 1, wherein a level of an uppermost surface of the insulating spacer is higher in a vertical direction than a level of an uppermost surface of each of the active layers.

3. The semiconductor light-emitting device as claimed in claim 1, wherein the lower portion of the first conductivity-type semiconductor layer has a flat plate shape in contact with lower surfaces of the rods.

4. The semiconductor light-emitting device as claimed in claim 1, wherein the second electrode layer is in contact with an upper surface of each of the second conductivity-type semiconductor layers and a portion of a side surface of each of the second conductivity-type semiconductor layers.

5. The semiconductor light-emitting device as claimed in claim 4, wherein, when viewed from a side cross-section, the second electrode layer has a concave-convex shape.

6. The semiconductor light-emitting device as claimed in claim 1, wherein the first conductivity-type semiconductor layer includes n-type gallium nitride, the second conductivity-type semiconductor layer includes p-type gallium nitride, and each of the active layers includes a quantum well layer and a quantum barrier layer.

7. The semiconductor light-emitting device as claimed in claim 1, wherein a distance between the rods is about 100 nm to about 2 μm, and each of the rods has a cylindrical, a quadrangular, or a hexagonal rod shape.

8. The semiconductor light-emitting device as claimed in claim 7, wherein a height of each of the rods is about 100 nm to about 10 μm, and a diameter of each of the upper surfaces of the rods is about 100 nm to about 10 μm.

9. The semiconductor light-emitting device as claimed in claim 7, wherein the insulating spacer has a thickness of about 50 nm to about 1 μm, the insulating spacer including silicon oxide, silicon nitride, or aluminum oxide.

10. The semiconductor light-emitting device as claimed in claim 1, wherein a length in a vertical direction of a sidewall of each of the second conductivity-type semiconductor layers contacting the insulating spacer is at least 50 nm.

11. A semiconductor light-emitting device, comprising:
a first conductivity-type semiconductor layer including mesa structures spaced apart from each other;
an active layer on an upper surface of each of the mesa structures;
a second conductivity-type semiconductor layer on an upper surface of the active layer;
an insulating spacer extending conformally between the mesa structures, the insulating spacer surrounding all sidewalls of the active layer, covering lower ends of sidewalls of the second conductivity-type semiconductor layer, and having a round upper outer wall;
a first electrode layer in contact with the first conductivity-type semiconductor layer; and
a second electrode layer filling an inner space of the insulating spacer and in contact with an upper surface of the second conductivity-type semiconductor layer and upper ends of the sidewalls of the second conductivity-type semiconductor layer.

12. The semiconductor light-emitting device as claimed in claim 11, wherein the active layer and the second conductivity-type semiconductor layer are in a space defined by the mesa structure and the insulating spacer.

13. The semiconductor light-emitting device as claimed in claim 11, wherein a lower surface of the second electrode layer has a concave-convex shape, and an upper surface of the second electrode layer has a flat shape.

14. The semiconductor light-emitting device as claimed in claim 11, wherein the active layer and the second conductivity-type semiconductor layer have a substantially same area.

15. The semiconductor light-emitting device as claimed in claim 11, wherein the active layer and the second conductivity-type semiconductor layer are aligned on each of the mesa structures to define a cylindrical column, the insulating spacer extending along sidewalls of the cylindrical column.

16. A semiconductor light-emitting device, comprising:
a sapphire substrate;
an undoped gallium nitride layer on the sapphire substrate;
an n-type gallium nitride layer including rods spaced apart from each other, the rods being in an upper portion of the n-type gallium nitride layer;
active layers on upper surfaces of the rods;
p-type gallium nitride layers on upper surfaces of the active layers, respectively;
an insulating spacer extending conformally between the rods, the insulating spacer surrounding all sidewalls of each of the active layers, and covering portions of sidewalls of each of the p-type gallium nitride layers;
an n-electrode layer in contact with a lower portion of the n-type gallium nitride layer; and
a p-electrode layer filling an inner space of the insulating spacer and in contact with the p-type gallium nitride layers.

17. The semiconductor light-emitting device as claimed in claim 16, wherein:
a vertical level of an uppermost surface of the insulating spacer is higher than a vertical level of each of the upper surfaces of the rods,
the vertical level of the uppermost surface of the insulating spacer is higher than a vertical level of each of the upper surfaces of the active layers, and
the vertical level of the uppermost surface of the insulating spacer is lower than a vertical level of an upper surface of each of the p-type gallium nitride layers.

18. The semiconductor light-emitting device as claimed in claim 16, wherein:
each of the active layers has a structure in which a quantum well layer and a quantum barrier layer are alternately disposed,
the quantum well layer includes an indium gallium nitride layer, and
the quantum barrier layer includes a gallium nitride layer or an indium aluminum gallium nitride layer.

19. The semiconductor light-emitting device as claimed in claim 16, wherein a height of each of the rods is about 100 nm to about 10 μm, a diameter of each of the upper surfaces of the rods is about 100 nm to about 10 μm, a distance between the rods is about 100 nm to about 2 μm, and a thickness of the insulating spacer is about 50 nm to about 1 μm.

20. The semiconductor light-emitting device as claimed in claim 16, wherein an upper outer wall of the insulating spacer is a rounded side wall, and each of the active layers and each of the p-type gallium nitride layers has substantially a same area.

21.-25. (canceled)
